(19) United States
(12) Patent Application Publication
(10) Pub. No.: US 2009/0162985 A1
(43) Pub. Date: Jun. 25, 2009

(54) Method of Fabricating Semiconductor Device

(76) Inventor: Dae Young Kim, Suwon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/258,489

(22) Filed: Oct. 27, 2008

(30) Foreign Application Priority Data
Dec. 24, 2007 (KR) 10-2007-0136091

(51) Int. Cl. H01L 21/336

(52) U.S. Cl. 438/308; 257/E21.424

(57) ABSTRACT

Methods of fabricating a semiconductor device are provided. An insulating layer can be formed on a semiconductor substrate, a sacrificial layer can be formed on the insulating layer, and a trench can be formed in the sacrificial layer. A first gate material layer can be formed on the sacrificial layer and in the trench, and a second gate material layer can be formed on the first gate material layer. A gate electrode can be formed by reacting the first gate material layer and the second gate material layer.

### CROSS-REFERENCE TO RELATED APPLICATION

The present application claims the benefit under 35 U.S.C. §119 of Korean Patent Application No. 10-2007-0136091, filed Dec. 24, 2007, which is hereby incorporated by reference in its entirety.

### BACKGROUND

As information processing technology develops, semiconductor devices continue to become smaller and more integrated.

Accordingly, the size of gate electrodes of semiconductor devices continues to become smaller. Thus, reducing the resistance of a gate electrode is very important in fabrication of semiconductor devices.

### BRIEF SUMMARY

Embodiments of the present invention provide methods of fabricating a semiconductor device including forming a gate electrode with low resistance.

In an embodiment, a method of fabricating a semiconductor device can comprise: forming an insulating layer on a semiconductor substrate; forming a sacrificial layer on the insulating layer; forming a trench in the sacrificial layer exposing a portion of the insulating layer; forming a metal layer on the sacrificial layer and in the trench; forming a first polysilicon layer on the metal layer; and forming a gate electrode by reacting the metal layer with the polysilicon layer.

In another embodiment, a method of fabricating a semiconductor device can comprise: forming an insulating layer on a semiconductor substrate; forming a sacrificial layer on the insulating layer; forming a trench in the sacrificial layer exposing a portion of the insulating layer; forming a first gate material layer on the sacrificial layer and in the trench; forming a second gate material layer on the first gate material layer; and forming a gate electrode by reacting the first gate material layer with the second gate material layer.

According to embodiments of the present invention, a first gate material layer can be formed in a trench in a sacrificial layer, and a second gate material layer can be formed on the first gate material layer.

Thus, the first gate material layer can make contact with the second gate material layer, thereby allowing the first gate material layer to easily react with the second gate material layer.

In an embodiment, the first gate material layer can be a metal layer, and the second gate material layer can be a polysilicon layer. T he metal layer can easily react with the polysilicon layer to form silicide.

Consequently, embodiments can provide a gate electrode having an approximately uniform distribution of silicide. Since the gate electrode can include silicide with an approximately uniform distribution, the resistance of the gate electrode can be lowered.

### BRIEF DESCRIPTION OF THE DRAWINGS

FIGS. 1 to 6 are cross-sectional views showing a method of fabricating a semiconductor device according to an embodiment of the present invention.

### DETAILED DESCRIPTION

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

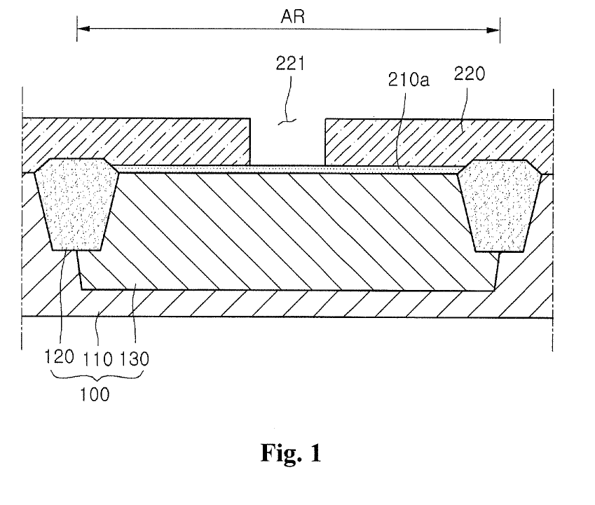

FIGS. 1 to 6 are cross-sectional views showing a method of fabricating a semiconductor device according to an embodiment of the present invention.

Referring to FIG. 1, isolation layers 120 can be formed on a semiconductor substrate 100 to define an active region AR. The isolation layers 120 can be formed through any suitable process known in the art, for example, a local oxidation of silicon (LOCOS) process or a shallow trench isolation (STI) process. In an embodiment, the semiconductor substrate can include lightly doped n-type impurities in an n-type impurity area 110.

Lightly doped p-type impurities can be implanted into the active area to form a p-type well 130. Accordingly, in an embodiment, the semiconductor substrate 100 can include an n-type impurity area 110, a p-type well 130, and an isolation layer 120. In an alternative embodiment, the n-type impurity area 110 can be a p-type impurity area, and the p-type well 130 can be an n-type well.

An insulating layer 210a can be formed on the semiconductor substrate 100. The insulating layer can be formed by, for example, subjecting the semiconductor substrate 100 to a thermal oxidation process or a chemical vapor deposition (CVD) process. In an embodiment, the insulating layer 210a can be an oxide layer.

After forming the insulating layer 210a, a nitride layer can be formed on the insulating layer 210a. In an embodiment, the nitride layer can have a thickness of from about 1400 Å to about 1500 Å. The nitride layer can be selectively etched to form a trench 221 and a sacrificial layer 220. In an embodiment, the trench 221 can be formed such that a portion of the insulating layer 210a is exposed.

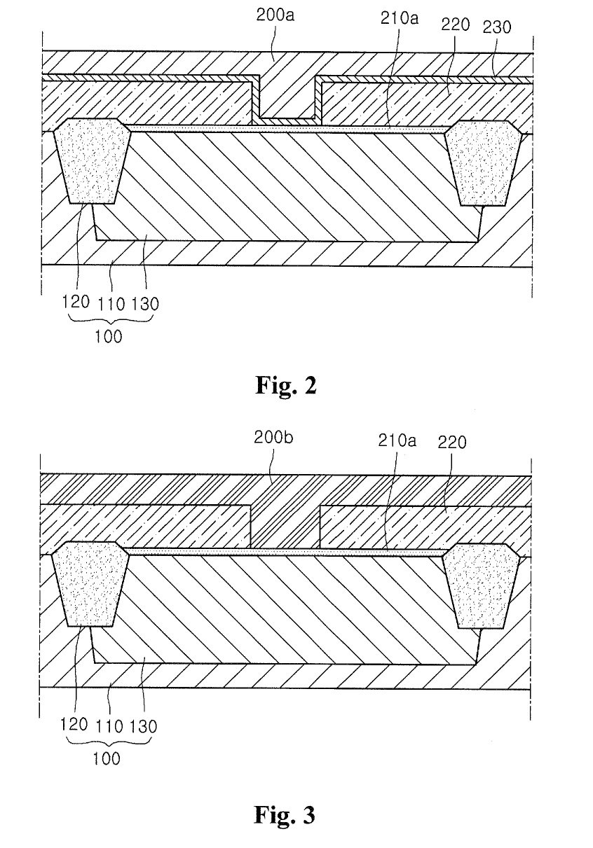

Referring to FIG. 2, a metal layer 230 can be formed on the sacrificial layer 220, including in the trench 221 and on the exposed portion of the insulating layer 210a. In an embodiment, the metal layer 230 can have a thickness of from about 100 Å to about 800 Å. The metal layer 230 can comprise any suitable material known in the art, for example, nickel, cobalt, titanium, platinum, or any combination thereof.

In an embodiment, the metal layer 230 can be formed through a sputtering process such that the metal layer 230 covers the sacrificial layer 220.

After forming the metal layer 230, a polysilicon layer 200a can be formed on the metal layer 230. In an embodiment, the polysilicon layer 200a can cover the metal layer 230, including a portion of the metal layer 230 in the trench 221.

In an embodiment, the polysilicon layer 200a can be formed through a low pressure chemical vapor deposition (LPCVD) process at a temperature of from about 640° C. to about 660° C.

Referring to FIG. 3, the metal layer 230 can react with the polysilicon layer 200a through a first rapid thermal process (RTP) to form a first silicide layer 200b. In an embodiment, the first RTP can be performed at a temperature of about 440° C. to about 460° C. for a period of time of about one minute.

In an embodiment, the metal layer 230 can include nickel. T he metal layer 230 can react with the polysilicon layer 200a as shown by Reaction 1, so that the first silicide layer 200b can include Ni₂Si.

2Ni+Si→Ni₂Si (Reaction 1)

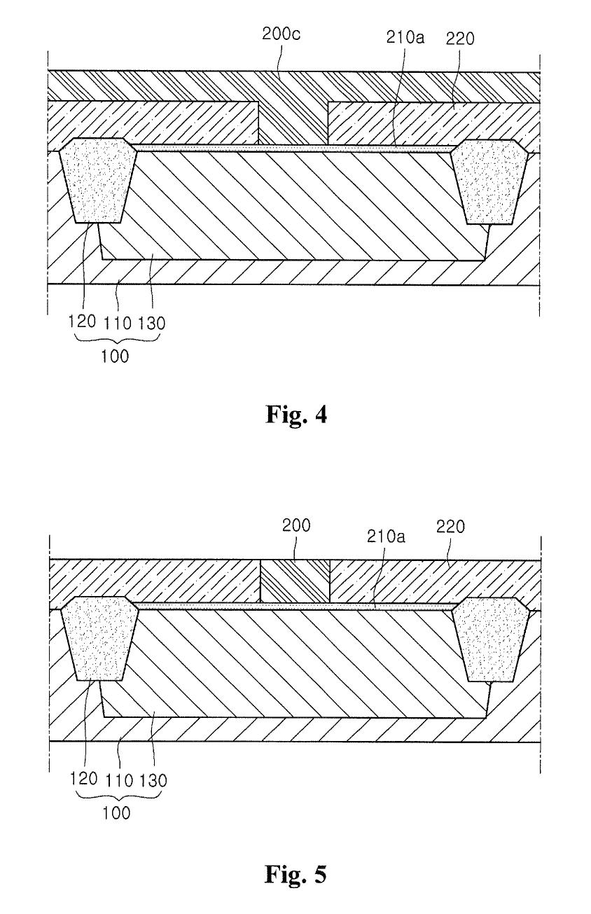

Referring to FIG. 4, a second silicide layer 200c can be formed by subjecting the first silicide layer 200b to a second RTP. In an embodiment, the second RTP can be performed at a temperature of from about 640° C. to about 670° C. for a period of time of from about one minute to about two minutes.

In embodiments where metal layer 230 includes nickel, the Ni₂Si formed through the first RTP can react with silicon remaining on the first silicide layer 200b, so that the second silicide layer 200c can include NiSi, as shown by Reaction 2.

Ni₂Si+Si→2NiSi (Reaction 2)

Referring to FIG. 5, a portion of the second silicide layer 200c formed on the sacrificial layer 220 can be removed. That is, a portion of the second silicide layer 200c that is not on the insulating layer 210a or in the trench 221 can be removed. The portion of the second silicide layer 200c can be removed through any suitable process known in the art, for example, a chemical mechanical polishing (CMP) process. Thus, the portion of the second silicide layer 200c in the trench 221 can be planarized with the sacrificial layer 220, thereby forming a gate electrode 200 in the trench 221. In an embodiment, the second silicide layer 200c can be planarized using the sacrificial layer 220 as a polish stop.

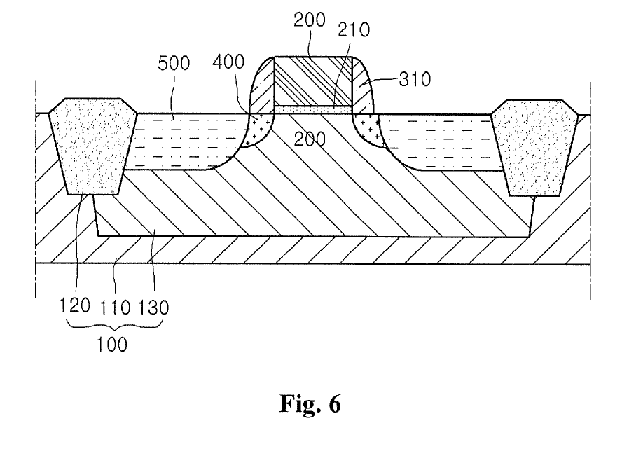

Referring to FIG. 6, after forming the gate electrode 200, the sacrificial layer 220 and a portion of the insulating layer 210a under the sacrificial layer 220 can be removed. A portion of the insulating layer 210a not under the sacrificial layer 220 can remain to form a gate insulating layer 210 between the gate electrode 200 and the semiconductor substrate 100.

In an embodiment, lightly doped n-type impurities can be implanted into the active region to form lightly doped drain (LDD) area 400, and a nitride layer can be formed on the semiconductor substrate 100. Then, a spacer 310 can be formed through an anisotropic etching process, such as an etchback process. In an alternative embodiment, p-type impurities can be implanted to form the LDD area 400 for a PMOS transistor.

Thereafter, source/drain regions 500 can be formed in the p-type well 130. In an embodiment, the source/drain regions 500 can be formed through an ion implantation process using the gate electrode 200 and the spacer 310 as an ion implantation mask. The n, a silicide layer can be formed on the source/drain regions 500.

According to the methods of fabricating a semiconductor device of the present invention, a metal layer can be formed in contact with a polysilicon layer. Thus, the metal layer can easily react with the polysilicon layer 200a through a first RTP, and a gate electrode can include silicide with a uniform (or approximately uniform) distribution.

That is, the gate electrode 200 can include silicide with a more uniform distribution than a semiconductor device fabricated by a related art method.

Additionally, the gate electrode of a semiconductor device fabricated according to methods of the present invention can have lower resistance than that of a gate electrode of a semiconductor device fabricated by a related art method. Thus, according to embodiments of the present invention, a semiconductor device can be fabricated having improved device characteristics and performance.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, comprising:
forming an insulating layer on a semiconductor substrate;
forming a sacrificial layer on the insulating layer;
forming a trench in the sacrificial layer exposing a portion of the insulating layer;
forming a metal layer on the sacrificial layer and in the trench;
forming a first polysilicon layer on the metal layer; and
forming a gate electrode by reacting the metal layer with the polysilicon layer.

2. The method according to claim 1, wherein forming the gate electrode comprises:
forming a first silicide layer by performing a first heat treatment process on the semiconductor substrate to react the metal layer with the polysilicon layer.

3. The method according to claim 2, wherein the first heat treatment process is a first rapid thermal process (RTP).

4. The method according to claim 2, wherein forming the gate electrode further comprises:
forming a second silicide layer by performing a second heat treatment process on the semiconductor substrate including the first silicide layer.

5. The method according to claim 4, wherein the second heat treatment process is a second RTP.

6. The method according to claim 4, wherein forming the gate electrode further comprises removing a portion of the second silicide layer that is not in the trench.

7. The method according to claim 6, wherein removing a portion of the second silicide layer comprises performing a chemical mechanical polishing process on the second silicide layer using the sacrificial layer as a polish stop.

8. The method according to claim 1, further comprising:
removing the sacrificial layer; and
removing a portion of the insulating layer that is not under the gate electrode.

9. The method according to claim 8, further comprising:
forming spacers at sidewalls of the gate electrode; and
forming source/drain regions in the semiconductor substrate.

10. The method according to claim 1, wherein the metal layer comprises nickel, cobalt, titanium, platinum, or any combination thereof.

11. The method according to claim 1, wherein the metal layer comprises nickel.

12. The method according to claim 1, wherein forming the polysilicon layer comprises performing a low pressure chemical vapor deposition process.

13. The method according to claim 1, wherein the metal layer has a thickness of from about 100 Å to about 800 Å.

14. The method according to claim 1, wherein the metal layer is formed such that a portion of the metal layer makes physical contact with the exposed portion of the insulating layer.

15. A method of fabricating a semiconductor device, comprising:
forming an insulating layer on a semiconductor substrate;
forming a sacrificial layer on the insulating layer;
forming a trench in the sacrificial layer exposing a portion of the insulating layer;
forming a first gate material layer on the sacrificial layer and in the trench;
forming a second gate material layer on the first gate material layer; and
forming a gate electrode by reacting the first gate material layer with the second gate material layer.

16. The method according to claim 15, wherein forming the gate electrode comprises:
performing a first heat treatment process on the semiconductor substrate to react the first gate material layer with the second gate material layer.

17. The method according to claim 16, wherein the first heat treatment process is a first rapid thermal process (RTP).

18. The method according to claim 15, further comprising:
removing the sacrificial layer; and
removing a portion of the insulating layer that is not under the gate electrode.

19. The method according to claim 18, further comprising:
forming spacers at sidewalls of the gate electrode; and
forming source/drain regions in the semiconductor substrate.

20. The method according to claim 15, wherein the first gate material layer is formed such that a portion of the first gate material layer makes physical contact with the exposed portion of the insulating layer.
